(19) United States
(12) Patent Application Publication
(10) Pub. No.: US 2020/0111861 A1
(43) Pub. Date: Apr. 9, 2020

(54) INTERCONNECT STRUCTURE, A DISPLAY SUBSTRATE AND A METHOD OF MANUFACTURING THE SAME

(71) Applicant: KunShan Go-Visionox Opto-Electronics Co., Ltd., KunShan (CN)

(72) Inventors: Kun HU, KunShan (CN); Yalong LI, KunShan (CN); Guizhou QIAO, KunShan (CN)

(21) Appl. No.: 16/706,874

(22) Filed: Dec. 9, 2019

Related U.S. Application Data
(63) Continuation of application No. PCT/CN2018/119002, filed on Dec. 3, 2018.

(30) Foreign Application Priority Data
Jun. 30, 2018 (CN) 201810703265.6

(51) Int. Cl. H01L 27/32; H01L 51/00; H05K 1/02; H01L 51/56; H01L 23/528; H01L 21/768

(52) U.S. Cl. CPC H01L 27/3276; H01L 51/0097; H05K 1/0283; H05K 2201/10128; H01L 23/528; H01L 21/768; H01L 2251/5338; H01L 51/56

(57) ABSTRACT

Disclosed is an interconnect structure, a display substrate and a method of manufacturing the same. The interconnect structure includes a first region and a second region connected to each other, the first region has a first stress, the second region has a second stress, the second stress is greater than the first stress, the first region includes a conductive wire, and the second region includes a nano-metal wire.

### CROSS-REFERENCES TO RELATED APPLICATIONS

This application is a continuation application of International Patent Application No. PCT/CN2018/119002 with an international filing date of Dec. 3, 2018, designating the United States, now pending, and further claims priority benefits to Chinese Patent Application No. 201810703265.6, filed on Jun. 30, 2018. The contents of all of the aforementioned applications are incorporated herein by reference.

### TECHNICAL FIELD

The disclosure relates to the field of display technologies, and more particularly to an interconnect structure, a display substrate and a method of manufacturing the same.

### BACKGROUND

Flexible display devices have powerful advantages, such as convenience in carrying, flexibility and free deformation. At present, as the flexible display technology becomes more and more mature, flexible display screens will gradually come into people's life, and flexible mobile devices will gradually become a main tool of daily life. It is predicted that flexible mobile devices will gradually replace traditional mobile devices (mobile phones, tablet PC, etc.) in the near future.

### SUMMARY

The disclosure discloses an interconnect structure, a display substrate and a method of manufacturing the same for solving the technical problem of easily broken of the interconnect structure, thereby improving the mechanical reliability of the interconnect structure and improving the reliability of the display device comprising the same.

In order to solve the above-mentioned technical problem, an embodiment of the disclosure provides an interconnect structure, including a first region and a second region connected to each other, the first region having a first stress, the second region having a second stress, the second stress being greater than the first stress, the first region comprising a conductive wire, and the second region comprising a nano-metal wire.

Optionally, the interconnect structure is a polyline structure, and an inflection point of the polyline structure constitutes the second region.

Optionally, in the interconnect structure, the second stress of the second region is equal to or more than 1.2 times of the first stress of the first region.

Optionally, in the interconnect structure, the second region has a pattern with a shape selected from the group consisting of quadrangle, pentagon, hexagon, circular arc, V-shape and any combination thereof, wherein the V-shape has an included angle selected from the group consisting of right angle, obtuse angle and acute angle.

Optionally, in the interconnect structure, the conductive wire comprises gold wire, silver wire or copper wire, and the nano-metal wire comprises nano silver wire, nano gold wire, nano platinum wire, nano-copper wire, nano cobalt wire or nano palladium wire.

Optionally, the interconnect structure is a straight line structure.

According to another aspect of the disclosure, an embodiment of the disclosure provides a display substrate, comprising a substrate and the above mentioned interconnect structure arranged on the substrate.

Optionally, the substrate is a flexible substrate made of a material selected from the group consisting of acrylic, polymethyl methacrylate, polyacrylonitrile-butadiene-styrene, polyamide, polyimide, polybenzimidazole polybutene, polybutylene terephthalate, polycarbonate, polyether-ether-ketone, polyetherimide, polyether sulfone, polyethylene, polyethylene terephthalate, polyethylene tetrafluoroethylene, polyethylene oxide, polyglycolic acid, polymethylpentene, polyoxymethylene, polyphenylene ether, polypropylene, polystyrene, polytetrafluoroethylene, polyurethane, polyvinyl chloride, polyvinyl fluoride, polyvinylidene chloride, polyvinylidene fluoride, styrene-acrylonitrile, and any combination thereof.

According to another aspect of the disclosure, an embodiment of the disclosure provides a method of manufacturing a display substrate, comprising providing a substrate; and forming an interconnect structure on the substrate, and the interconnect structure comprising a first region and a second region connected to each other, the first region having a first stress, the second region having a second stress, and the second stress being greater than the first stress.

Optionally, said forming an interconnect structure on the substrate comprises the steps of: forming a conductive wire pattern on the substrate, the conductive wire pattern constituting the first region of the interconnect structure; and forming a nano-metal wire pattern on the substrate, the nano-metal wire pattern being connected to the conductive wire pattern, and the nano-metal wire pattern constituting the second region of the interconnect structure.

Optionally, said forming a conductive wire pattern on the substrate comprises the steps of: forming a metal film on the substrate; and etching the metal film to form the conductive wire pattern.

Optionally, said forming a nano-metal wire pattern on the substrate comprises the steps of: coating a nano-metal layer on the conductive wire pattern and exposed substrate; and removing a portion of the nano-metal layer to form the nano-metal wire pattern.

Optionally, the conductive wire pattern comprises a plurality of straight metal wires that are not crossed with each other.

Optionally, the conductive wire pattern comprises a first metal wire pattern arranged in parallel in a first direction and a second metal wire pattern alternately arranged in parallel in a second direction, and the first direction is perpendicular to the second direction.

Optionally, the nano-metal wire pattern connects the first metal wire pattern and the second metal wire pattern.

Optionally, at least one of the first metal wire pattern and the second metal wire pattern is a stripe structure.

Optionally, the nano-metal wire pattern is a nano-silver wire pattern.

Optionally, said coating a nano-metal layer is carried out with a method selected from the group consisting of inkjet printing, spray coating, gravure printing, letterpress printing, flexographic printing, nano-imprinting, screen printing, blade coating, spin coating, stylus plotting, slit coating and flow coating.

Optionally, said removing a portion of the nano-metal layer is carried out by laser etching or mechanical scraping.

Optionally, the second metal wire pattern comprises a first position and a second position spaced from each other in the first direction, and the second metal wire pattern comprises metal wires parallel to each other in the second direction and alternately arranged in the first position and the second position.

The disclosure has the following advantages:

The interconnect structure of the disclosure comprises a first region and a second region connected to each other, the first region has a first stress, the second region has a second stress, the second stress is greater than the first stress, the first region comprises a conductive wire, and the second region comprises a nano-metal wire. As the nano-metal wire has good electrical conductivity and good ductility (folding endurance), arranging the nano-metal wire in the second region which has greater stress can prevent broken of the second region during bending because the nano-metal wire is not easy to break, thereby effectively improving the mechanical reliability of the interconnect structure. The reliability of the display device can be improved by applying the display substrate comprising the interconnection structure to the display device.

### BRIEF DESCRIPTION OF THE DRAWINGS

FIG. 1 shows a schematic top view of a display substrate;

FIG. 2 shows a flowchart of a method of manufacturing a display substrate in an embodiment of the disclosure;

FIG. 3 shows a flowchart of the steps of forming an interconnect structure in an embodiment of the disclosure.

FIGS. 4 to 8 show a schematic top view of each step in the method of manufacturing a display substrate in an embodiment of the disclosure;

FIG. 9 shows a schematic top view of a display substrate in another embodiment of the disclosure;

FIG. 10 shows a schematic top view of a display substrate in another embodiment of the disclosure;

FIG. 11 shows a schematic top view of a display substrate in another embodiment of the disclosure.

### DETAILED DESCRIPTION OF THE INVENTION

Interconnect structure is one of the core mechanisms in a flexible display device, such as the interconnect structure for electrodes in a thin film transistor array, the interconnect structure for electrodes in an organic light emitting layer, and the interconnect structure for touch electrodes in a touch panel. An interconnect structure is used for electrically connecting or leading out of electrodes. However, the interconnect structure of a flexible display device is easily broken, resulting in failure of the flexible display device.

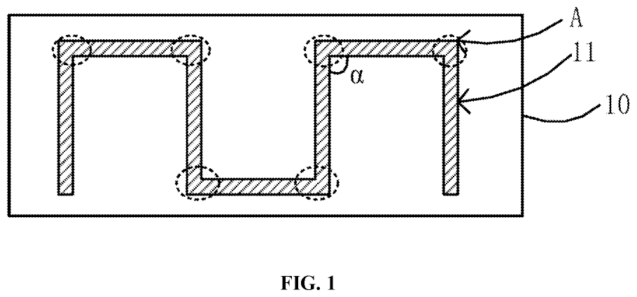

FIG. 1 shows a top view of a display substrate in a flexible display device. As shown in FIG. 1, the display substrate comprises a flexible substrate 10 and an interconnect structure 11 formed on the flexible substrate 10. Wherein the interconnect structure 11 is a polyline structure comprising a plurality of metal wires connected head to tail. The connecting region of two adjacent metal wires constitutes an inflection point A of the interconnect structure 11, and the two adjacent metal wires has an included angle a at the inflection point A, and the included angle a may be a right angle (as shown in FIG. 1), an obtuse angle or an acute angle. However, the applicant has found that when the above display substrate is applied to a flexible display device, stress concentration (that is, the stress generated at the inflection point A is greater than the stress generated in other regions) is easy to occur in some areas (such as in the inflection points A) of the interconnect structure 11 when the flexible display device is bent and deformed, and the interconnect structure may be broken at the inflection points A, causing failure of the flexible display device.

In addition, when the interconnect structure has a straight line metal wire pattern, different stresses are generated in different regions of the interconnect structure, and stress concentrated regions may also fracture during the bending process.

Based on the above findings, an embodiment of the disclosure provides an interconnect structure, comprising a first region and a second region connected to each other, the first region having a first stress, the second region having a second stress, the second stress being greater than the first stress, the first region comprising a conductive wire, and the second region comprising a nano-metal wire.

Accordingly, according to another aspect of the disclosure, an embodiment of the disclosure also provides a display substrate, comprising a substrate and an interconnect structure arranged on the substrate.

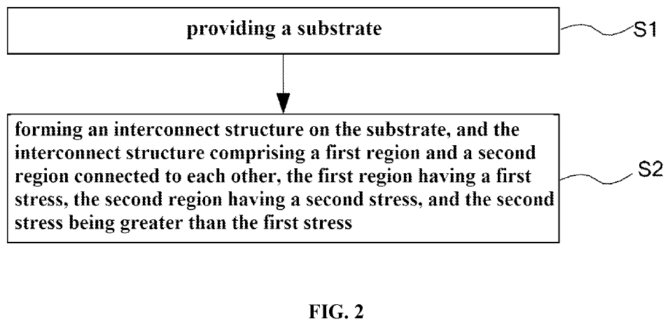

In addition, according to another aspect of the disclosure, an embodiment of the disclosure further provides a method of manufacturing a display substrate, as shown in FIG. 2, comprising: step Si, providing a substrate; and step S2, forming an interconnect structure on the substrate, and the interconnect structure comprising a first region and a second region connected to each other, the first region having a first stress, the second region having a second stress, and the second stress being greater than the first stress.

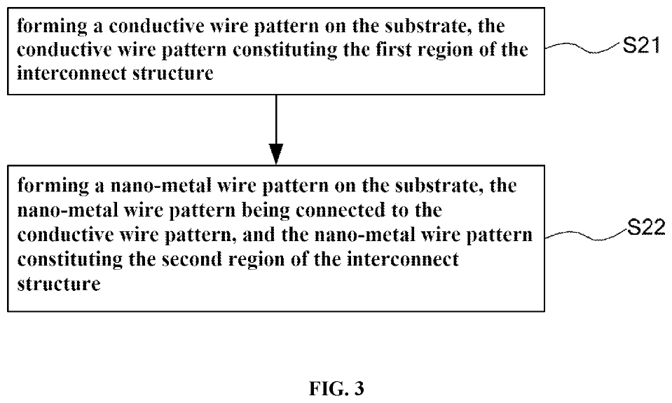

As shown in FIG. 3, said forming an interconnect structure on the substrate comprises the steps of:

Step S21, forming a conductive wire pattern on the substrate, the conductive wire pattern constituting the first region of the interconnect structure; and

Step S22, forming a nano-metal wire pattern on the substrate, the nano-metal wire pattern being connected to the conductive wire pattern, and the nano-metal wire pattern constituting the second region of the interconnect structure.

The interconnect structure in the disclosure has a first region and a second region connected to each other, the first region has a first stress, the second region has a second stress, the second stress is greater than the first stress, the first region comprises a conductive wire, and the second region comprises a nano-metal wire. As the nano-metal wire has good electrical conductivity and good ductility (folding endurance), arranging the nano-metal wire in the second region which has greater stress can prevent broken of the second region during bending because the nano-metal wire is not easy to break, thereby effectively improving the mechanical reliability of the interconnect structure. The reliability of the display device can be improved by applying the display substrate comprising the interconnection structure to the display device.

The interconnect structure, the display substrate and the method of manufacturing the same of the disclosure will be described in more detail below with reference to the flowcharts and schematic diagrams, wherein preferred embodiments of the disclosure are shown. The content of the disclosure is not limited to the following embodiments, and other embodiments improved by a person with ordinary skill in the art through conventional technical means are also within the protection scope of the disclosure.

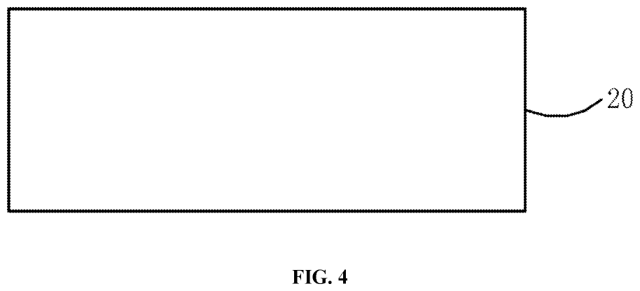

First, step S1 is performed to provide a substrate. Preferably, the substrate is a flexible substrate 20, as shown in FIG. 4. The flexible substrate 20 can be made of a material selected from the group consisting of acrylic, polymethyl methacrylate (PMMA), polyacrylonitrile-butadiene-styrene (ABS), polyamide (PA), polyimide (PI), polybenzimidazole polybutene (PB), polybutylene terephthalate (PBT), polycarbonate (PC), polyether-ether-ketone (PEEK), polyetherimide (PEI), polyether sulfone (PES), polyethylene (PE), polyethylene terephthalate (PET), polyethylene tetrafluoroethylene (ETFE), polyethylene oxide, polyglycolic acid (PGA), polymethylpentene (PMP), polyoxymethylene (POM), polyphenylene ether (PPE), polypropylene (PP), polystyrene (PS), polytetrafluoroethylene (PTFE), polyurethane (PU), polyvinyl chloride (PVC), polyvinyl fluoride (PVF), polyvinylidene chloride (PVDC), polyvinylidene fluoride (PVDF), styrene-acrylonitrile (SAN), and any combination thereof. Preferably, in the present embodiment, the flexible substrate 20 is made of PI.

Next, step S2 is performed to form an interconnect structure on the substrate. The interconnect structure has a first region and a second region connected to each other, the first region has a first stress, the second region has a second stress, and the second stress is greater than the first stress. Specifically, under the existing process conditions, in order to meet actual needs, the interconnect structure may be designed into various structural forms, such as a straight line structure, a circular arc structure, or a V-shaped structure, or any combination thereof. When a display panel comprising the interconnect structure deforms due to bending, different stresses generated in different regions of the interconnect structure. In the embodiments of the disclosure, the regions wherein stress are easily concentrated in the interconnection structure are generally termed as the second region, and the regions where stress are not easily concentrated are generally termed as the first region, so the stress of the second region is greater than the stress of the first region. Further, in the present embodiment, the stress of the second region is equal to or larger than 1.2 times of the stress of the first region.

Since greater stress is generated in the second region during bending, in order to improve the mechanical reliability of the interconnect structure and to prevent broken of the interconnect structure, the interconnect structure is formed on the substrate according to the following steps:

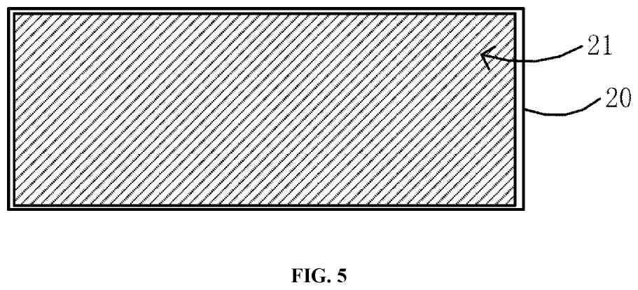

Step S21 is performed to form a conductive wire pattern on the substrate, and the conductive wire pattern constitutes the first region of the interconnect structure. Preferably, the conductive wire pattern is made of metal, such as gold wire, silver wire or copper wire, etc. Specifically, a metal film 21 is firstly formed on the flexible substrate 20, as shown in FIG. 5. The metal film 21 can be prepared by physical vapor deposition (PVD), such as but not limited to evaporation, sputtering, etc. The metal thin film 21 is made of a material which may be but not limited to gold, silver or copper. Then, a desired conductive wire pattern 21′ is formed in the metal film 21 through a photolithography process and an etching process. The conductive wire pattern 21′ constitutes the first region of the interconnect structure. In addition, in the present embodiment, the interconnect structure comprises an inflection point when the interconnect structure is a polyline structure, and the inflection point constitutes the second region, and the remaining portions constitute the first region.

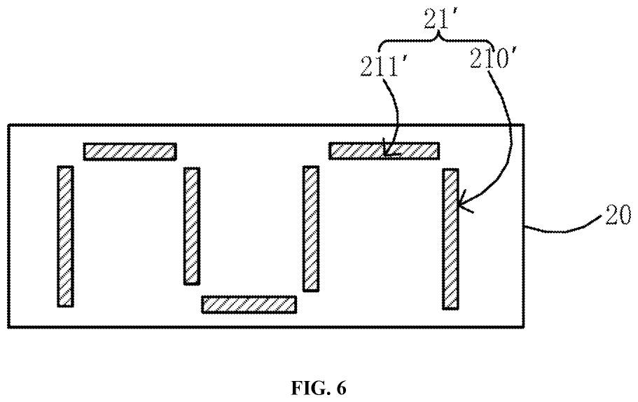

Preferably, in the present embodiment, the conductive wire pattern 21′ does not comprise an inflection point (compared with FIG. 1), but comprises a plurality of straight metal wires that are not crossed with each other. Specifically, as shown in FIG. 6, the conductive wire pattern 21′ comprises a first metal wire pattern 210′ arranged in parallel in a first direction and a second metal wire pattern 211′ alternately arranged in parallel in a second direction, the first metal wire pattern 210′ is not crossed with the second metal wire pattern 211′, and the first direction is perpendicular to the second direction. By referring to FIG. 6, the second metal wire pattern 211′ comprises a first position and a second position spaced from each other by the first metal wire pattern 210′ in the first direction (see the upper position and lower position in FIG. 6). Wherein, the second metal wire pattern 211′ is alternately arranged in parallel in the second direction means that the second metal wire pattern 211′ comprises metal wires parallel to each other in the second direction and alternately arranged in the first position and the second position.

Illustratively, as shown in FIG. 6, each of the first metal wire pattern 210′ and the second metal wire pattern 211′ may be a stripe structure, and the conductive wire pattern 21′ comprising the first metal wire pattern 210′ and the second metal wire pattern 211′ constitutes the first region of the interconnect structure. Specifically, the metal film of the second region (at the inflection point) is removed by etching when the conductive wire pattern 21′ is formed on the flexible substrate 20. The etched area of the metal film at the inflection point may depend on the intensity of the actually generated stress. For example in the present embodiment, the included angle at the inflection point of the interconnect structure is a right angle (i.e., the first direction is perpendicular to the second direction). In other embodiments, the included angle may also be obtuse angle or acute angle. Since the corresponding layout of the metal wire patterns can be easily obtained by those skilled in the art on the basis of the above description, no details are required herein.

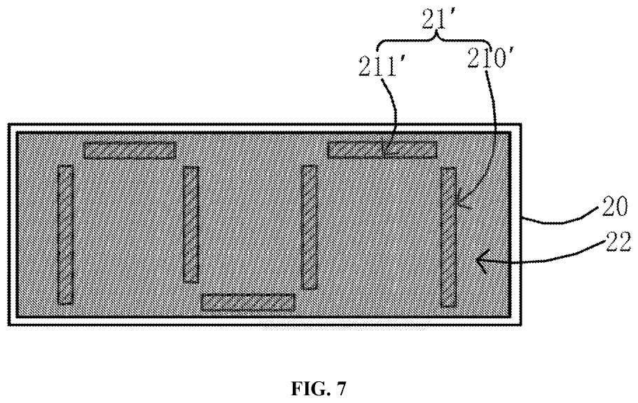

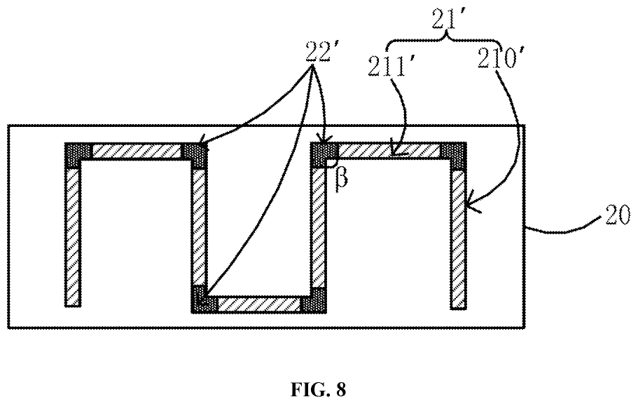

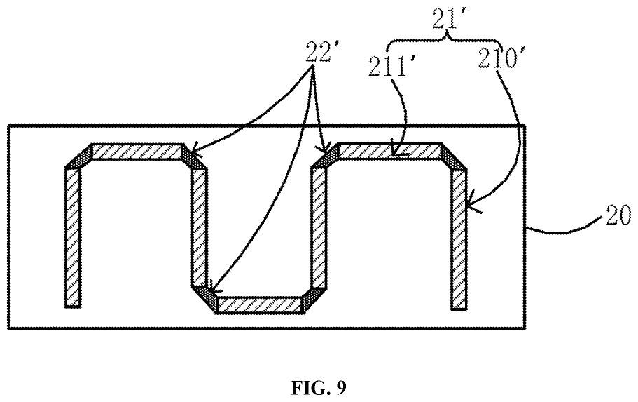

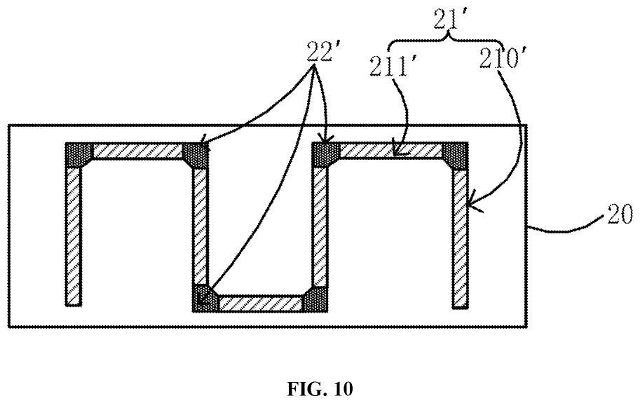

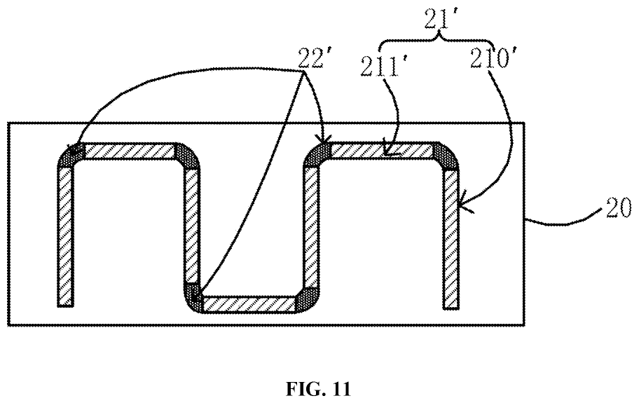

Next, step S22 is performed to form a nano-silver wire pattern on the substrate. The nano-metal wire pattern is electrically connected to the conductive wire pattern, and the nano-metal wire pattern constitutes the second region of the interconnect structure. Preferably, the nano-metal wire pattern is a nano-silver wire pattern in the present embodiment, because nano silver is a silvery metal in a general state and has excellent conductivity and good folding endurance. In addition, the nano-metal wire pattern may also be other nano-metal wire patterns, such as nano-gold (Au), nano-platinum (Pt), nano-copper (Cu), nano-cobalt (Co), nano-palladium (Pd), etc. Specifically, as shown in FIG. 7, a nano-silver layer 22 is firstly coated on the exposed area of the flexible substrate 20 and on the conductive wire pattern 21′. The nano-silver layer 22 can be coated with a method selected from the group consisting of inkjet printing, spray coating, gravure printing, letterpress printing, flexographic printing, nano-imprinting, screen printing, blade coating, spin coating, stylus plotting, slit coating and flow coating. Then, as shown in FIG. 8, a portion of the nano-silver layer 22 is removed by laser etching or mechanical scraping according to the layout of the second region in the interconnect structure, forming nano-silver wire pattern 22′ at the second region (at the inflection point). The nano-silver wire pattern 22′ connects the first metal wire pattern 210′ and the second metal wire pattern 211′, and the obtained interconnect structure comprises the conductive wire pattern 21′of the first region and the nano-silver wire pattern 22′ of the second region. In the present embodiment, the nano-silver wire pattern 22′ has a V-shape which has an included angle f3 of right angle. In other embodiments, the included angle 0 of the V-shape may also be obtuse angle or acute angle. In addition, in other embodiments, the nano-silver wire pattern 22′ may also be designed to have a shape of quadrangle (as shown in FIG. 9), pentagon (as shown in FIG. 10), hexagon (the schematic diagram is not shown), or circular arc (as shown in FIG. 11), etc. Furthermore, the nano-silver wire pattern 22′ may also be a combination of two or more of V-shape, quadrangle, pentagon, hexagon, and circular arc.

In addition, the interconnect structure is designed as a polyline structure for example in the above embodiment. In another embodiment, the interconnect structure may also be designed as a straight line structure. When the interconnect structure has a straight line metal wire pattern, different stresses are generated in different regions of the interconnect structure during the bending process. The greater the degree of the bending deformation, the more concentrated the stress. On this basis, nano-metal wire is used in the region where the greater stress is generated, and conducting wire is used in other regions, thereby improving the mechanical reliability of the interconnect structure. The method of manufacturing the straight line interconnect structure can be easily obtained by those skilled in this art by referring to the method of manufacturing the polyline interconnect structure, so no detailed description are required herein.

The display substrate manufactured by the above method comprises a flexible substrate 20 and an interconnect structure arranged on the flexible substrate 20, and the interconnect structure comprises a conductive wire pattern 21′ of the first region and a nano-silver wire pattern 22′ of the second region. Obviously, the display substrate is not limited to be manufactured by the above method in the disclosure.

When the above display substrate is applied to a flexible display device, the reliability of the flexible display device can be improved because the mechanical reliability of the interconnect structure of the display substrate is improved.

In summary, the interconnect structure of the disclosure comprises a first region where stress concentration does not easily occur and a second region where stress concentration easily occurs, connected with each other. The first region has a first stress, the second region has a second stress, and the second stress is greater than the first stress. As the nano-metal wire has good electrical conductivity and good ductility (folding endurance), arranging the nano-metal wire in the second region which has greater stress can prevent broken of the second region during bending because the nano-metal wire is not easy to break, thereby effectively improving the mechanical reliability of the interconnect structure. The reliability of the display device can be improved by applying the display substrate comprising the interconnection structure to the display device.

Apparently, various changes and modifications in other different forms can be made by those skilled in the art on the basis of the aforementioned description without departing from the spirit and scope of the disclosure. Thus, if such modifications and variations to the disclosure fall within the scope of the claims and their equivalents in the disclosure, it is also intended to include such modifications and variations.

1. An interconnect structure, comprising a first region and a second region connected to each other, the first region having a first stress, the second region having a second stress, the second stress being greater than the first stress, the first region comprising a conductive wire, and the second region comprising a nano-metal wire.

2. The interconnect structure according to claim 1, wherein the interconnect structure is a polyline structure, and an inflection point of the polyline structure constitutes the second region.

3. The interconnect structure according to claim 1, wherein the second stress of the second region equal to or more than 1.2 times of the first stress of the first region.

4. The interconnect structure according to claim 1, wherein the second region has a pattern with a shape selected from the group consisting of quadrangle, pentagon, hexagon, circular arc, V-shape and any combination thereof, wherein the V-shape has an included angle selected from the group consisting of right angle, obtuse angle and acute angle.

5. The interconnect structure according to claim 1, wherein the conductive wire comprises gold wire, silver wire or copper wire, and the nano-metal wire comprises nano silver wire, nano gold wire, nano platinum wire, nano-copper wire, nano cobalt wire or nano palladium wire.

6. The interconnect structure according to claim 1, wherein the interconnect structure is a straight line structure.

7. A display substrate, comprising a substrate and the interconnect structure according to claim 1 arranged on the substrate.

8. The display substrate according to claim 7, wherein the substrate is a flexible substrate made of a material selected from the group consisting of acrylic, polymethyl methacrylate, polyacrylonitrile-butadiene-styrene, polyamide, polyimide, polybenzimidazole polybutene, polybutylene terephthalate, polycarbonate, polyether-ether-ketone, polyetherimide, polyether sulfone, polyethylene, polyethylene terephthalate, polyethylene tetrafluoroethylene, polyethylene oxide, polyglycolic acid, polymethylpentene, polyoxymethylene, polyphenylene ether, polypropylene, polystyrene, polytetrafluoroethylene, polyurethane, polyvinyl chloride, polyvinyl fluoride, polyvinylidene chloride, polyvinylidene fluoride, styrene-acrylonitrile, and any combination thereof.

9. A method of manufacturing a display substrate, comprising:
providing a substrate; and
forming an interconnect structure on the substrate, and the interconnect structure comprising a first region and a second region connected to each other, the first region having a first stress, the second region having a second stress, the second stress being greater than the first stress, the first region comprising a conductive wire, and the second region comprising a nano-metal wire.

10. The method according to claim 9, wherein said forming an interconnect structure on the substrate comprises the steps of:
forming a conductive wire pattern on the substrate, the conductive wire pattern constituting the first region of the interconnect structure; and
forming a nano-metal wire pattern on the substrate, the nano-metal wire pattern being connected to the conductive wire pattern, and the nano-metal wire pattern constituting the second region of the interconnect structure.

11. The method according to claim 10, wherein said forming a conductive wire pattern on the substrate comprises the steps of:
forming a metal film on the substrate; and
etching the metal film to form the conductive wire pattern.

12. The method according to claim 10, wherein said forming a nano-metal wire pattern on the substrate comprises the steps of:
coating a nano-metal layer on the conductive wire pattern and the exposed substrate; and
removing a portion of the nano-metal layer to form the nano-metal wire pattern.

13. The method according to claim 10, wherein the conductive wire pattern comprises a plurality of straight metal wires that are not crossed with each other.

14. The method according to claim 13, wherein the conductive wire pattern comprises a first metal wire pattern and a second metal wire pattern,
wherein the first metal wire pattern is arranged in parallel in a first direction,
the second metal wire pattern is spaced apart by the first metal wire pattern in the first direction, and is alternately arranged in an upper position and a lower position of the first metal wire pattern and is parallel to each other in a second direction, and
the first direction is perpendicular to the second direction.

15. The method according to claim 14, wherein the nano-metal wire pattern connects the first metal wire pattern and the second metal wire pattern.

16. The method according to claim 14, wherein at least one of the first metal wire pattern and the second metal wire pattern is a stripe structure.

17. The method according to claim 10, wherein the nano-metal wire pattern is a nano-silver wire pattern.

18. The method according to claim 12, wherein said coating a nano-metal layer is carried out with a method selected from inkjet printing, spray coating, gravure printing, letterpress printing, flexographic printing, nano-imprinting, screen printing, blade coating, spin coating, stylus plotting, slit coating and flow coating.

19. The method according to claim 12, wherein said removing a portion of the nano-metal layer is carried out by laser etching or mechanical scraping.

20. The method according to claim 14, wherein the second metal wire pattern comprises a first position and a second position spaced from each other in the first direction, and the second metal wire pattern comprises metal wires parallel to each other in the second direction and alternately arranged in the first position and the second position.
